(19) United States
(12) Patent Application Publication
(10) Pub. No.: US 2024/0393684 A1
(43) Pub. Date: Nov. 28, 2024

(54) METHOD OF FORMING PATTERNS

(71) Applicant: SAMSUNG SDI CO., LTD., Yongin-si (KR)

(72) Inventors: Jongpil HO, Suwon-si (KR); Hyungrang MOON, Suwon-si (KR); Seung HAN, Suwon-si (KR); Taeho KIM, Suwon-si (KR); Gyeong Ryeong BAK, Suwon-si (KR); Si-Kyun PARK, Suwon-si (KR); Taeksoo KWAK, Suwon-si (KR); Gyeonghun PARK, Suwon-si (KR); Myoungsoo SONG, Suwon-si (KR); Jin-Hee BAE, Suwon-si (KR); Minsoo KIM, Suwon-si (KR)

(21) Appl. No.: 18/617,447

(22) Filed: Mar. 26, 2024

(30) Foreign Application Priority Data
May 23, 2023 (KR) 10-2023-0066535
Mar. 19, 2024 (KR) 10-2024-0037581

(51) Int. Cl. G03F 7/004; G03F 7/16; G03F 7/32

(52) U.S. Cl. CPC G03F 7/0042; G03F 7/168; G03F 7/325

(57) ABSTRACT

Provided is a method of forming patterns which includes coating a metal-containing resist composition on a substrate; drying and heating to form a metal-containing resist film on the substrate; exposing the metal-containing resist film using a patterned mask; and coating a developer composition to remove unexposed regions to form a resist pattern A thickness of the resist film after development is increased by about 5 to about 100% compared to the thickness of the resist film before development, and

a surface of the resist film after the development may include about 5 to about 20 at % of at least one selected from a phosphorus element and a sulfur element, based on the total number of atoms.

### CROSS-REFERENCE TO RELATED APPLICATION

The present application claims priority to and the benefit of Korean Patent Application No. 10-2023-0066535 filed on May 23, 2023, and Korean Patent Application No. 10-2024-0037581 filed Mar. 19, 2024, the entire disclosures of which are incorporated by reference herein.

### BACKGROUND

### 1. Field

Embodiments of this disclosure relate to a method of forming patterns including developing.

### 2. Description of the Related Art

In recent years, a semiconductor industry has seen a substantially continuous reduction of critical dimensions, and this dimensional reduction would benefit from new types (or kinds) of high-performance photoresist materials and a patterning method that satisfy a desire for processing and patterning with increasingly smaller features.

Chemically amplified (CA) photoresists are designed to secure high sensitivity, but because an elemental makeup thereof (mainly, in smaller quantities of O, F, and S, C) lowers absorbance at a wavelength of about 13.5 nm and as a result, reduces sensitivity, the photoresists may suffer more difficulties partially under the extreme ultraviolet (EUV) light exposure. The CA photoresists may have difficulties due to roughness issues in small feature sizes, and due partially to the nature of acid catalyst processes, LER (line edge roughness) experimentally turns out to increase as a photospeed decreases. Due to these drawbacks and issues of the CA photoresist a new type (or kind) of high-performance photoresists is required in the semiconductor industry.

It would be beneficial to develop a photoresist securing excellent etching resistance and resolution and concurrently (e.g., simultaneously), improving sensitivity and enhancing CD (critical dimension) uniformity and LER (line edge roughness) characteristics in the photolithography process.

### SUMMARY

Some example embodiments of the present disclosure provide a method of forming patterns including developing including coating a developer composition to form a resist pattern.

A method of forming patterns according to some example embodiments includes coating a metal-containing resist composition on a substrate; performing a heat treatment including drying and heating to form a metal-containing resist film on the substrate; exposing the metal-containing resist film using a patterned mask; and coating a developer composition to remove unexposed regions to form a resist pattern,
wherein a thickness of the metal-containing resist film after development is increased by about 5 to about 100% compared to the thickness of the metal-containing resist film before development, and
a surface of the metal-containing resist film after the development may include about 5 to about 20 at % of at least one selected from a phosphorus element and a sulfur element, based on the total number of atoms.

The developer composition may include an additive including at least one selected from a phosphoric acid compound, a phosphorous acid-based compound, a hypophosphorous acid-based compound, and a sulfonic acid-based compound, and an organic solvent.

The additive may be included in an amount of about 0.01 to about 10 wt %.

The phosphorous acid-based compound may be at least one of phosphonic acid, methyl phosphonic acid, ethyl phosphonic acid, butyl phosphonic acid, hexyl phosphonic acid, n-octyl phosphonic acid, tetradecyl phosphonic acid, octadecyl phosphonic acid, phenyl phosphonic acid, vinyl phosphonic acid, aminomethyl phosphonic acid, methylenediamine tetra methylene phosphonic acid, ethylenediamine tetra methylene phosphonic acid, 1-amino 1-phosphonooctyl phosphonic acid, etidronic acid, 2-aminoethyl phosphonic acid, 3-aminopropyl phosphonic acid, 4-methylphenyl phosphonic acid, 3-methylphenyl phosphonic acid, 2-methylphenyl phosphonic acid, 4-aminophenyl phosphonic acid, 3-aminophenyl phosphonic acid, 2-aminophenyl phosphonic acid, 3-hydroxy phenyl phosphonic acid, 4-hydroxy phenyl phosphonic acid, 2-hydroxy phenyl phosphonic acid, 6-hydroxyhexyl phosphonic acid, decyl phosphonic acid, diphosphonic acid, methylene di phosphonic acid, nitrilotrimethylene triphosphonic acid, 1H, 1H, 2H, 2H-perfluorooctanephosphonic acid, cyclohexylmethyl phosphonic acid, 2-thienylmethyl phosphonic acid, 4-fluoro phenyl phosphonic acid, benzyl phosphonic acid, or a combination thereof.

The hypophosphorous acid-based compound may be at least one of diphenylphosphinic acid, bis(4-methoxyphenyl) phosphinic acid, phosphinic acid, bis(hydroxymethyl)phosphinic acid, phenylphosphinic acid, p-(3-aminopropyl)-p-butylphosphonic acid, or a combination thereof.

The sulfonic acid-based compound may be at least one of p-toluenesulfonic acid, benzenesulfonic acid, p-dodecylbenzenesulfonic acid, 1,4-naphthalenedisulfonic acid, methanesulfonic acid, phenylmethanesulfonic acid, 1-octanesulfonic acid, 4-ethenylbenzenesulfonic acid, 2-methylbenzenesulfonic acid, ethanesulfonic acid, 2,5-dimethylbenzenesulfonic acid, 2,4-dimethylbenzenesulfonic acid, allylsulfonic acid, 1-butanesulfonic acid, 1-propanesulfonic acid, 2-propanesulfonic acid, vinylbenzenesulfonic acid, hexanesulfonic acid, heptanesulfonic acid, or a combination thereof.

A metal compound included in the metal-containing resist composition may include at least one selected from an organic oxy group-containing tin compound and an organic carbonyloxy group-containing tin compound.

The metal compound may be represented by Chemical Formula 1.

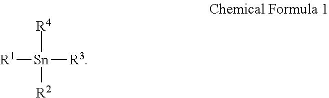

In Chemical Formula 1,
R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, and L^{a}-O—R^{a} (wherein L^{a} is a substituted or unsubstituted C1 to C20 alkylene group and R^{a} is a substituted or unsubstituted C1 to C20 alkyl group),
R² to R⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, —OR^{b} or —OC(═O)R^{c},
at least one of R² to R⁴ are each independently —OR^{b} or —OC(═O)R^{c},
R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

The method of forming patterns according to some example embodiments may implement a fine pattern having a relatively increased width (thickness) of the resist pattern by reducing a space between resist patterns while reducing bridges and improving LER characteristics.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1-3 are cross-sectional views illustrating a process sequence in order to explain a method of forming patterns according to embodiments of the present disclosure.

FIG. 4 is a set of scanning electron micrograph images comparing the thickness of resist films after development.

FIG. 5 is a graph showing the result of X-ray photoelectron spectroscopy (XPS) analysis of resist films after development.

FIG. 6 is a set of scanning electron micrograph images showing resist patterns after development.

### DETAILED DESCRIPTION

Hereinafter, referring to the drawings, embodiments of the present disclosure are described in more detail. In the following description of the subject matter of the present disclosure, well-known functions or constructions may not be described in order to clarify the description of embodiments of the present disclosure.

In order to clearly illustrate embodiments of the present disclosure, certain description and relationships may be omitted, and throughout the disclosure, the same or similar configuration elements are designated by the same reference numerals. Also, because the size and thickness of each configuration shown in the drawing may be arbitrarily shown for better understanding and ease of description, the present disclosure is not necessarily limited thereto.

In the drawings, the thickness of layers, films, panels, regions, etc., may be exaggerated for clarity. In the drawings, the thickness of a part of layers or regions, etc., may be exaggerated for clarity. It will be understood that if an element such as a layer, film, region, or substrate is referred to as being “on” another element, it can be directly on the other element or intervening elements may also be present.

In the present disclosure, “substituted” refers to replacement of a hydrogen atom by deuterium, a halogen group, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a cyano group. “Unsubstituted” means that a hydrogen atom remains as a hydrogen atom without being replaced by another substituent.

In the present disclosure, the term “alkyl group” means a linear or branched aliphatic hydrocarbon group, unless otherwise defined. The alkyl group may be a “saturated alkyl group” that does not contain any double or triple bonds.

The alkyl group may be a C1 to C20 alkyl group. For example, the alkyl group may be a C1 to C10 alkyl group or a C1 to C6 alkyl group. For example, a C1 to C4 alkyl group means that the alkyl chain contains 1 to 4 carbon atoms, and may be selected from methyl, ethyl, propyl, iso-propyl, n-butyl, iso-butyl, sec-butyl, and t-butyl.

Examples of the alkyl group include a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, and the like.

In the present disclosure, if a definition is not otherwise provided, the term “cycloalkyl group” refers to a monovalent cyclic aliphatic hydrocarbon group.

In the present disclosure, if a definition is not otherwise provided, the term “alkenyl group” is a linear or branched aliphatic hydrocarbon group, and refers to an aliphatic unsaturated alkenyl group containing one or more double bonds.

In the present disclosure, if a definition is not otherwise provided, the term “alkynyl group” is a linear or branched aliphatic hydrocarbon group, and refers to an unsaturated alkynyl group containing one or more triple bonds.

In the present disclosure, “aryl group” means a substituent in which all elements of a cyclic substituent have p-orbitals, and these p-orbitals form a conjugate and may include monocyclic, polycyclic or fused ring (e.g., rings that share adjacent pairs of carbon atoms) functional groups.

Hereinafter, a method of forming patterns according to some example embodiments will be described in more detail with reference to drawings.

A method of forming patterns according to some example embodiments includes coating a metal-containing resist composition on a substrate, drying and heating to form a metal-containing resist film on the substrate, exposing the metal-containing resist film using a patterned mask and coating a developer composition to remove unexposed regions to form a resist pattern,
wherein a thickness of the resist film after development is increased by about 5 to about 100% compared to the thickness of the resist film before development, and
a surface of the resist film after the development may include about 5 to about 20 at % of at least one selected from a phosphorus element and a sulfur element, based on the total number of atoms.

In order to reduce a space gap of the resist, a gap between mask patterns may be narrowed, but there is an issue of generating bridges between lines due to diffraction of light during the exposure and thus resultantly increasing LER.

If a developer having high solubility is used, a space interval may be widened even at the same energy, but on the contrary, if a developer having low solubility is used, the bridges also may be generated between the lines due to undissolved components remaining in some of the spaces.

However, resist patterns formed according to embodiments of the method of forming the patterns according to the present disclosure, because the resist film includes about 5 at % to about 20 at % of at least one selected from a phosphorus element and a sulfur element on the surface after the development and thus has about 5% to about 100% increased thickness after the development to before the development, may implement an effect of reducing the space interval without (or substantially without) the bridges and thus improve LER characteristics.

The P and S components among the developer components are adsorbed onto the resist surface to increase the thickness of the patterns as well as maintain a shape of the patterns and resultantly, reduce the space interval.

In some embodiments, the method of forming patterns using the metal-containing resist composition may include coating the metal-containing resist composition on the substrate on which a thin film is formed in a method of spin coating, slit coating, inkjet printing, and/or the like and drying it to form a resist film. The metal-containing resist composition may include a tin-based compound, for example the tin-based compound may include at least one selected from an organic oxy group-containing tin compound and an organic carbonyloxy group-containing tin compound.

For example, the metal compound included in the metal-containing resist composition may be represented by Chemical Formula 1.

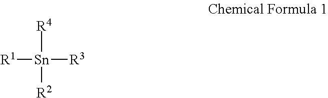

In Chemical Formula 1,
R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, and -L^{a}-O—R^{a} (wherein L^{a} is a substituted or unsubstituted C1 to C20 alkylene group and R^{a} is a substituted or unsubstituted C1 to C20 alkyl group),
R² to R⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, —OR^{b} or —OC(═O)R^{c},
at least one of R² to R⁴ are each independently —OR^{c} or —OC(═O)R^{d},
R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.
R^{c} and R^{d} may each independently be a substituted or unsubstituted C1 to C20 alkyl group.

Next, a first heat treatment process of heating the substrate on which the metal-containing photoresist film is formed is performed. The first heat treatment process may be performed at a temperature of about 80° C. to about 120° C. In embodiments of this process, the solvent is evaporated, and the metal-containing photoresist film may be more firmly adhered to the substrate.

Then, the photoresist film is selectively exposed to light using a patterned mask.

In some embodiments, examples of light that may be used in the exposure process may include not only light having a short wavelength such as i-line (wavelength 365 nm), KrF excimer laser (wavelength of 248 nm), ArF excimer laser (wavelength of 193 nm), but also light having a high energy wavelength such as EUV (Extreme UltraViolet light, wavelength of 13.5 nm), E-Beam (electron beam), etc.

In some embodiments, the light for the exposure according to some example embodiments may be light having a short wavelength in a range from about 5 nm to about 150 nm but also light having a high energy wavelength such as EUV (Extreme UltraViolet light; wavelength: about 13.5 nm), E-Beam (electron beam), and/or the like.

In the forming of the photoresist pattern, a negative-type pattern may be formed.

The exposed region of the photoresist film has a solubility different from that of the unexposed region of the photoresist film as a polymer is formed by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist film becomes difficult to be dissolved in a developer solution.

Then, the developing utilizing a developer composition may be performed.

In some embodiments, a photoresist pattern corresponding to the negative tone image may be completed by coating a developer composition to dissolve the photoresist film corresponding to the unexposed region and then removing the photoresist film.

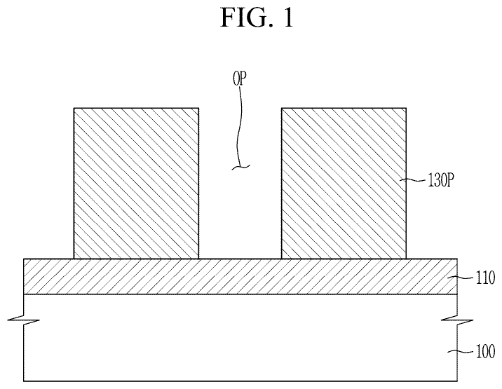

FIGS. 1-3 are cross-sectional views illustrating a process sequence in order to explain embodiments of a method of forming patterns.

Referring to FIG. 1, the exposed photoresist film is developed to form a photoresist pattern 130P on the substrate 100.

In some example embodiments, the exposed photoresist film may be developed to remove an unexposed region of the photoresist film, and the photoresist pattern 130P including the exposed region of the photoresist film may be formed. The photoresist pattern 130P may include a plurality of openings OP.

In some example embodiments, the development of the photoresist film may be performed through an NTD (negative-tone development) process. In some embodiments, the metal-containing photoresist developer composition according to an embodiment may be used as a developer composition.

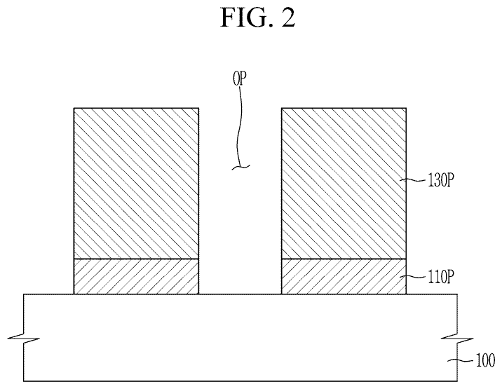

Referring to FIG. 2, the photoresist pattern 130P is used to process a feature layer 110 in the result of FIG. 1.

For example, the feature layer 110 is processed through various suitable processes of etching a feature layer 110 exposed through the openings OP of the photoresist pattern 130P, injecting impurity ions into the feature layer 110, forming an additional film on the feature layer 110 through the openings OP, deforming a portion of the feature layer 110 through the openings OP, and/or the like. FIG. 2 illustrates an example process of processing a feature pattern 110P by etching the feature layer 110 exposed through the openings OP.

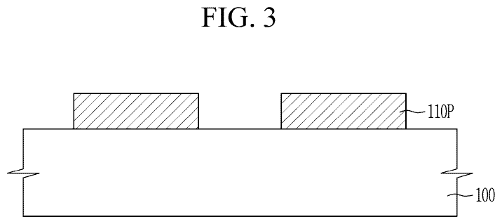

Referring to FIG. 3, the photoresist pattern 130P remaining on the feature pattern 110P is removed in the result of FIG. 2. In order to remove the photoresist pattern 130P, ashing and/or stripping processes may be used.

According to some example embodiments, the thickness of the resist film after development may be increased by 5 to 100% compared to the thickness of the resist film before development.

The thickness of the resist film after the development may be increased by including at least one selected from a phosphorus element and a sulfur element on the surface of the resist pattern.

For example, at least one selected from the phosphorus element and the sulfur element may be included in an amount of about 5 to about 20 at %, based on the total number of atoms.

For example, the developer composition may include an additive including at least one selected from a phosphoric acid compound, a phosphorous acid-based compound, a hypophosphorous acid-based compound, and a sulfonic acid-based compound, and an organic solvent.

The phosphorus element and sulfur element included in the surface of the resist film after the development may be derived from additives in a developer composition.

The additive may be included in an amount of about 0.01 to about 10 wt % based on total 100 wt % of the developer composition. In some embodiments, the additive may be included in an amount of about 0.01 to about 7 wt %, about 0.01 to about 5 wt %, about 0.01 to about 3 wt %, or about 0.01 to about 1 wt %.

For example, the phosphorous acid-based compound may be at least one of phosphonic acid, methyl phosphonic acid, ethyl phosphonic acid, butyl phosphonic acid, hexyl phosphonic acid, n-octyl phosphonic acid, tetradecyl phosphonic acid, octadecyl phosphonic acid, phenyl phosphonic acid, vinyl phosphonic acid, aminomethyl phosphonic acid, methylenediamine tetra methylene phosphonic acid, ethylenediamine tetra methylene phosphonic acid, 1-amino 1-phosphonooctyl phosphonic acid, etidronic acid, 2-aminoethyl phosphonic acid, 3-aminopropyl phosphonic acid, 4-methylphenyl phosphonic acid, 3-methylphenyl phosphonic acid, 2-methylphenyl phosphonic acid, 4-aminophenyl phosphonic acid, 3-aminophenyl phosphonic acid, 2-aminophenyl phosphonic acid, 3-hydroxy phenyl phosphonic acid, 4-hydroxy phenyl phosphonic acid, 2-hydroxy phenyl phosphonic acid, 6-hydroxyhexyl phosphonic acid, decyl phosphonic acid, diphosphonic acid, methylene di phosphonic acid, nitrilotrimethylene triphosphonic acid, 1H, 1H, 2H, 2H-perfluorooctanephosphonic acid, cyclohexylmethyl phosphonic acid, 2-thienylmethyl phosphonic acid, 4-fluorophenyl phosphonic acid, benzyl phosphonic acid, or a combination thereof.

For example, the hypophosphorous acid-based compound may be at least one of diphenylphosphinic acid, bis(4-methoxyphenyl) phosphinic acid, phosphinic acid, bis(hydroxymethyl)phosphinic acid, phenylphosphinic acid, p-(3-aminopropyl)-p-butylphosphinic acid, or a combination thereof.

For example, the sulfonic acid-based compound may be at least one of p-toluenesulfonic acid, benzenesulfonic acid, p-dodecylbenzenesulfonic acid, 1,4-naphthalenedisulfonic acid, methanesulfonic acid, phenylmethanesulfonic acid, 1-octanesulfonic acid, 4-ethenylbenzenesulfonic acid, 2-methylbenzenesulfonic acid, ethanesulfonic acid, 2,5-dimethylbenzenesulfonic acid, 2,4-dimethylbenzenesulfonic acid, allylsulfonic acid, 1-butanesulfonic acid, 1-propanesulfonic acid, 2-propanesulfonic acid, vinylbenzenesulfonic acid, hexanesulfonic acid, heptanesulfonic acid, or a combination thereof.

Examples of the organic solvent included in the metal-containing photoresist developer composition according to the embodiment may include at least one selected from ether, alcohol, glycol ether, aromatic hydrocarbon compounds, ketone, and ester, but are not limited thereto. For example, the organic solvent may include ethyleneglycolmonomethylether, ethyleneglycolmonoethylether, methylcellosolveacetate, ethylcellosolveacetate, diethyleneglycolmethylether, diethyleneglycolethylether, propyleneglycol, propyleneglycolmethylether (PGME), propyleneglycolmethyletheracetate (PGMEA), propyleneglycolethylether, propyleneglycolethyletheracetate, propyleneglycolpropyletheracetate, propyleneglycolbutylether, propyleneglycolbutyletheracetate, ethanol, propanol, isopropylalcohol, isobutylalcohol, 4-methyl-2-pentenol (which may also be referred to as methyl isobutyl carbinol (MIBC)), hexanol, 1-methoxy-2-propanol, 1-ethoxy-2-propanol, ethyleneglycol, propyleneglycol, heptanone, propylenecarbonate, butylene carbonate, toluene, xylene, methylethylketone, cyclopentanone, cyclohexanone, 2-hydroxy ethyl propionate, 2-hydroxy-2-methyl ethyl propionate, ethoxy ethyl acetate, hydroxy ethyl acetate, 2-hydroxy-3-methylmethyl butanoate, 3-methoxy methyl propionate, 3-methoxy ethyl propionate, 3-ethoxy ethyl propionate, 3-ethoxy methyl propionate, methyl pyruvate, ethyl pyruvate, ethyl acetate, butyl acetate, ethyl lactate, butyl lactate, gamma-butyrolactone, methyl-2-hydroxyisobutyrate, methoxybenzene, n-butyl acetate, 1-methoxy-2-propyl acetate, methoxyethoxy propionate, ethoxyethoxy propionate, or a combination thereof, but is not limited thereto.

If the other additives to be further described herein below are included, the organic solvent may be included in a balance amount except for the components.

The developer composition may further include at least one other additive selected from a surfactant, a dispersant, a moisture absorbent, and a coupling agent.

The surfactant may serve to improve coating uniformity and improve wetting of the photoresist composition. In some example embodiments, the surfactant may be a sulfuric acid ester salt, a sulfonic acid salt, a phosphoric acid ester, a soap, an amine salt, a quaternary ammonium salt, a polyethylene glycol, an alkylphenol ethylene oxide adduct, a polyhydric alcohol, a nitrogen-containing vinyl polymer, or a combination thereof, but is not limited thereto. For example, the surfactant may include an alkylbenzenesulfonate salt, an alkylpyridinium salt, polyethylene glycol, and/or a quaternary ammonium salt. If the photoresist composition includes the surfactant, the surfactant may be included in an amount of about 0.001 wt % to about 3 wt % based on a total weight of the photoresist composition.

The dispersant may serve to uniformly (e.g., substantially uniformly) disperse each component constituting the photoresist composition in the photoresist composition. In an embodiment, the dispersant may be an epoxy resin, polyvinyl alcohol, polyvinyl butyral, polyvinylpyrrolidone, glucose, sodium dodecyl sulfate, sodium citrate, oleic acid, linoleic acid, or a combination thereof but is not limited thereto. If the photoresist composition includes the dispersant, the dispersant may be included in an amount of about 0.001 wt % to about 5 wt % based on a total weight of the photoresist composition.

The moisture absorbent may serve to prevent or reduce adverse effects by moisture in the photoresist composition. For example, the moisture absorbent may serve to prevent or reduce oxidation of the metal included in the photoresist composition by moisture. In an embodiment, the moisture absorbent may be polyoxyethylene nonylphenolether, polyethylene glycol, polypropylene glycol, polyacrylamide, or a combination thereof, but is not limited thereto. If the photoresist composition includes the moisture absorbent, the moisture absorbent may be included in an amount of about 0.001 wt % to about 10 wt % based on a total weight of the photoresist composition.

The coupling agent may serve to improve adhesion to the lower film if the photoresist composition is coated on the lower film. In an embodiment, the coupling agent may include a silane coupling agent. The silane coupling agent may be vinyltrimethoxysilane, vinyltriethoxysilane, vinyl trichlorosilane, vinyltris(3-methoxyethoxy)silane, 3-methacryloxypropyltrimethoxysilane, 3-acryloxypropyl trimethoxysilane, p-styryl trimethoxysilane, 3-methacryloxypropylmethyldimethoxysilane, 3-methacryloxypropylmethyldiethoxysilane, and/or trimethoxy[3-(phenylamino)propyl]silane, but is not limited thereto. If the photoresist composition includes the coupling agent, the coupling agent may be included in an amount of about 0.001 wt % to about 5 wt % based on a total weight of the photoresist composition.

As described above, the photoresist pattern formed by exposure to not only light having a short wavelength such as i-line (wavelength of 365 nm), KrF excimer laser (wavelength of 248 nm), ArF excimer laser (wavelength of 193 nm), but also light having high energy such as an EUV (Extreme UltraViolet light; wavelength of 13.5 nm) or an E-beam (electron beam) may have a thickness width of about 5 nm to about 100 nm. For example, the photoresist pattern may be formed to have a thickness width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In some embodiments, the photoresist pattern may have a pitch having a half-pitch of less than or equal to about 50 nm, for example less than or equal to about 40 nm, for example less than or equal to about 30 nm, for example less than or equal to about 20 nm, for example less than or equal to about 15 nm, and a line width roughness of less than or equal to about 10 nm, less than or equal to about 5 nm, less than or equal to about 3 nm, or less than or equal to about 2 nm.

Hereinafter, embodiments of the present disclosure will be described in more detail through examples relating to the preparation of the aforementioned metal-containing photoresist developer composition. However, the technical features of the present disclosure are not limited by the following examples.

### Preparation of Metal-Containing Photoresist Developer Composition

In a polypropylene (PP) bottle, an organic solvent and additives were mixed together in each composition shown in Table 1 and then, shaken at room temperature (25° C.) to completely dissolve them. Subsequently, the obtained solution was filtered through a PTFE filter having a pore size of 1 μm to obtain a developer composition.

TABLE 1

| | Developer composition | |
|---|---|---|
| | Organic solvent | Additive |
| | (wt %) | (wt %) |
| Example 1 | PGMEA (99.99) | vinyl phosphonic acid (0.01) |
| Example 2 | PGMEA (99.9) | vinyl phosphonic acid (0.1) |
| Example 3 | PGMEA (99.5) | vinyl phosphonic acid (0.5) |
| Example 4 | PGMEA (99.3) | vinyl phosphonic acid (0.7) |
| Example 5 | PGMEA (99.0) | vinyl phosphonic acid (1.0) |
| Example 6 | MIBC (99.9) | vinyl phosphonic acid (0.1) |
| Example 7 | PGMEA (99.9) | methanesulfonic acid (0.1) |
| Comparative | PGMEA (100) | — |
| Example 1 | | |
| Comparative | PGMEA (99.0) | acetic acid (1.0) |
| Example 2 | | |
| Comparative | PGMEA (99.9) | triphenylphosphate (0.1) |
| Example 3 | | |

### Preparation of Metal-Containing Photoresist Composition

An organometallic compound having a structural unit represented by Chemical Formula C was dissolved in 4-methyl-2-pentanol at a concentration of 1 wt % and then, filtered through a 0.1 μm Polytetrafluoroethylene (PTFE) syringe filter to prepare a metal-containing photoresist composition.

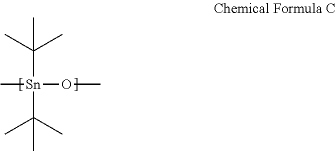

### Evaluation 1: Measurement of Pattern Thickness and XPS Analysis

After spin-coating hexamethyldisilazane (HMDS) to form a hydrophobic surface on an 8-inch silicon wafer, the prepared metal-containing photoresist (PR) composition was spin-coated at 1,500 rpm for 30 seconds on the treated wafer and then, heat-treated at 160° C. for 60 seconds to manufacture a coated wafer.

Onto the wafer, EUV light (Lawrence Berkeley National Laboratory Micro Exposure Tool, MET) was projected. Herein, pad exposure time was adjusted, so that an incremental EUV dose was applied to each pad.

Subsequently, the resist and the substrate were exposed on a hot plate at 180° C. for 90 seconds and then, post-exposure baked (PEB). The baked films were dipped in each developer according to Examples 1 to 7 and Comparative Examples 1 to 3 for 30 seconds and additionally washed with the same developer for 15 seconds to form a negative tone image, that is, to remove a non-exposed coating region. Finally, another hot-plate baking at 240° C. for 60 seconds was performed to complete the process.

The coated wafer was measured with respect to a residual resist thickness of the exposed pads at 70° at a wavelength range of 280 nm to 1,000 nm by using an ellipsometer M2000 made by J. A. Woolam.

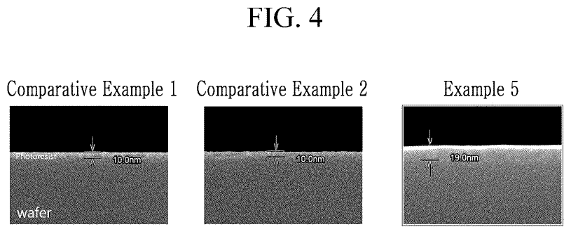

The thickness measurement results were shown in Table 2 and FIG. 4.

The thickness increase rate was calculated according to Equation 1 below:

$$[ \{ ( Thickness of photoresist film after development ) - ( Thickness of photoresist film before development ) \} / ( Thickness of photoresist film after development ) ] \times 100 \qquad [ Equation 1 ]$$

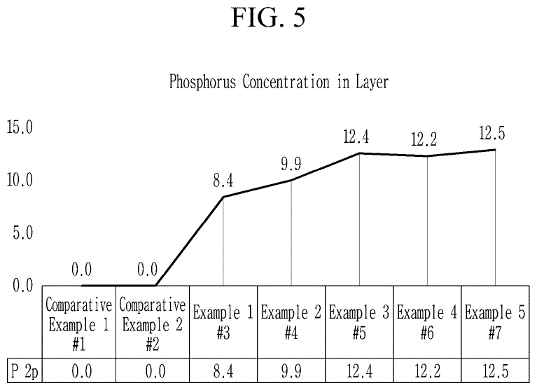

A component analysis of the residual resists was performed through XPS (x-ray photoelectron spectroscopy) (AXIS SUPRA, KRATOS Analytical Ltd.), and the results are shown in FIG. 5. The analysis was performed in an XPS-monochromatic mode by setting a beam size to be 700 μm, source power to be 150 W for wide scan and 225 W for narrow scan, and resolution to be 20 eV at an interval of 0.1 eV respectively for C1s, O1s, P2p, Sn3d, and S3p during the narrow scan, and was measured under the standard of surface thickness of 50 Å.

### Evaluation 2: CD Measurement

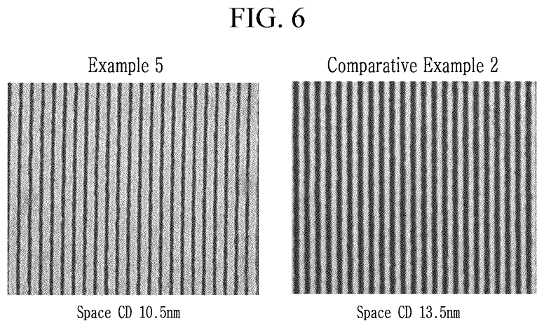

The developers were evaluated through injection in the developing process during the coating-exposure-development process for manufacturing a pattern wafer. The pattern wafer, on which line/space CD (Critical Dimension) patterns are formed, when the process has been completed, was transferred to GC-5000 CD-SEM measuring equipment made by Hitachi Ltd. to measure a CD (Critical Dimension) size in a region with a half-pitch of 14 nm out of mask patterns, and a minimum value of space CD's, which is a distance between lines, is shown in Table 2 and FIG. 6.

TABLE 2

| | Thickness of | Thickness of | | | |
|---|---|---|---|---|---|
| | photoresist | photoresist | Thickness | XPS | |
| | film before | film after | Increase | analysis | Minimum |
| | development | development | Rate | (P or S | Space CD |
| | (Å) | (Å) | (%) | ratio, %) | (@14 nm) |
| Example 1 | 125 | 135 | 8 | 8.4 | 11.9 |
| Example 2 | 123 | 150 | 22 | 9.9 | 10.5 |
| Example 3 | 125 | 180 | 44 | 12.1 | 10.4 |
| Example 4 | 128 | 210 | 64 | 12.2 | 10.3 |
| Example 5 | 128 | 250 | 95 | 12.5 | 10.1 |
| Example 6 | 123 | 150 | 22 | 9 | 11.5 |
| Example 7 | 125 | 150 | 20 | 12 | 10.8 |
| Comparative | 125 | 120 | Decrease | 0 | Resolution |
| Example 1 | | | | | is not |
| | | | | | available |
| Comparative | 124 | 120 | Decrease | 0 | 13.5 |
| Example 2 | | | | | |
| Comparative | 125 | 150 | 20 | 4.5 | Resolution |
| Example 3 | | | | | is not |
| | | | | | available |

* HP: half pitch reference)

Referring to Table 2, the metal-containing photoresist developer compositions according to Examples 1 to 7, compared with the metal-containing photoresist developer compositions according to Comparative Examples 1 to 3, exhibited a little residue in the dissolved space region as well as reduced space CD due to an increase in a thickness of the resist films after the development and thereby, excellent resolution and reduced bridges and residues.

FIG. 4 is a scanning electron micrograph comparing the thickness of resist films after development.

Referring to FIG. 4, when a developer composition to which a sulfonic acid-based compound (Example 5) was used, compared with when there was no treatment with a developer (Comparative Example 1) or when a developer composition to which organic acid was added (Comparative Example 2) was used, a thickness of a photoresist film exhibits was increased.

FIG. 5 is a graph showing the result of XPS analysis of resist films after development.

Referring to FIG. 5, as the XPS analysis results of the resist films after the development, the resist films turned out to include a P component. Accordingly, additive components in the developer composition were adsorbed onto the surface of the resist films.

FIG. 6 is a scanning electron micrograph showing resist patterns after development.

Referring to FIG. 6, when the P or S component among the additive components was included, as the P and S component was adsorbed onto the surface of the resist films, a thickness of resist patterns increases, but bridges were reduced due to a little dissolution residue even at a narrow space CD (10.5 nm), resultantly realizing patterns having excellent resolution. This effect enabled minimization or reduction of a semiconductor line width by minimizing or reducing a size of space portions of the patterns.

Hereinbefore, certain embodiments of the present disclosure have been described and illustrated, however, it should be apparent to a person having ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure.

### DESCRIPTION OF SYMBOLS

100: substrate OP: opening
110: feature layer
110P: feature pattern 130P: photoresist pattern

What is claimed is:

1. A method of forming patterns, comprising:
coating a metal-containing resist composition on a substrate;
drying and heating to form a metal-containing resist film on the substrate;
exposing the metal-containing resist film using a patterned mask; and
coating a developer composition to remove unexposed regions to form a resist pattern,
wherein a thickness of the metal-containing resist film after development is increased by about 5 to about 100% compared to a thickness of the metal-containing resist film before development,
a surface of the metal-containing resist film after the development comprises about 5 to about 20 at % of at least one selected from a phosphorus element and a sulfur element, based on the total number of atoms.

2. The method as claimed in claim 1, wherein:
the developer composition comprises an additive comprising at least one selected from a phosphoric acid compound, a phosphorous acid-based compound, a hypophosphorous acid-based compound, and a sulfonic acid-based compound, and an organic solvent.

3. The method as claimed in claim 2, wherein:
the additive is included in an amount of about 0.01 to about 10 wt %.

4. The method as claimed in claim 2, wherein:
the phosphorous acid-based compound is at least one of phosphonic acid, methyl phosphonic acid, ethyl phosphonic acid, butyl phosphonic acid, hexyl phosphonic acid, n-octyl phosphonic acid, tetradecyl phosphonic acid, octadecyl phosphonic acid, phenyl phosphonic acid, vinyl phosphonic acid, aminomethyl phosphonic acid, methylenediamine tetra methylene phosphonic acid, ethylenediamine tetra methylene phosphonic acid, 1-amino 1-phosphonooctyl phosphonic acid, etidronic acid, 2-aminoethyl phosphonic acid, 3-aminopropyl phosphonic acid, 4-methylphenyl phosphonic acid, 3-methylphenyl phosphonic acid, 2-methylphenyl phosphonic acid, 4-aminophenyl phosphonic acid, 3-aminophenyl phosphonic acid, 2-aminophenyl phosphonic acid, 3-hydroxy phenyl phosphonic acid, 4-hydroxy phenyl phosphonic acid, 2-hydroxy phenyl phosphonic acid, 6-hydroxyhexyl phosphonic acid, decyl phosphonic acid, diphosphonic acid, methylene di phosphonic acid, nitrilotrimethylene triphosphonic acid, 1H, 1H, 2H, 2H-perfluorooctanephosphonic acid, cyclohexylmethyl phosphonic acid, 2-tienylmethyl phosphonic acid, 4-fluoro phenyl phosphonic acid, benzyl phosphonic acid, or a combination thereof.

5. The method as claimed in claim 2, wherein:
the hypophosphorous acid-based compound is at least one of diphenylphosphinic acid, bis(4-methoxyphenyl) phosphinic acid, phosphinic acid, bis(hydroxymethyl)phosphinic acid, phenylphosphinic acid, p-(3-aminopropyl)-p-butylphosphinic acid, or a combination thereof.

6. The method as claimed in claim 2, wherein:
the sulfonic acid-based compound is at least one of p-toluenesulfonic acid, benzenesulfonic acid, p-dodecylbenzenesulfonic acid, 1,4-naphthalenedisulfonic acid, methanesulfonic acid, phenylmethanesulfonic acid, 1-octanesulfonic acid, 4-ethenylbenzenesulfonic acid, 2-methylbenzenesulfonic acid, ethanesulfonic acid, 2,5-dimethylbenzenesulfonic acid, 2,4-dimethylbenzenesulfonic acid, allylsulfonic acid, 1-butanesulfonic acid, 1-propanesulfonic acid, 2-propanesulfonic acid, vinylbenzenesulfonic acid, hexanesulfonic acid, heptanesulfonic acid, or a combination thereof.

7. The method as claimed in claim 1, wherein:
a metal compound included in the metal-containing resist composition comprises at least one selected from an organic oxy group-containing tin compound and an organic carbonyloxy group-containing tin compound.

8. The method as claimed in claim 1, wherein:
a metal compound included in the metal-containing resist composition is represented by Chemical Formula 1: 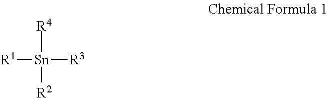
wherein, in Chemical Formula 1,
R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, and L^{a}-O—R^{a} (wherein L^{a} is a substituted or unsubstituted C1 to C20 alkylene group and R^{a} is a substituted or unsubstituted C1 to C20 alkyl group),
R² to R⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, —OR^{b} or —OC(═O)R^{c},
at least one of R² to R⁴ are each independently selected from —OR^{b} or —OC(═O)R^{c},
R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.
